(19) United States
(12) Patent Application Publication
(10) Pub. No.: US 2025/0080109 A1
(43) Pub. Date: Mar. 6, 2025

(54) GATE DRIVER STAGE, AND METHOD FOR OPERATING A GATE DRIVER STAGE

(71) Applicant: Robert Bosch GmbH, Stuttgart (DE)

(72) Inventors: Dick Scholten, Stuttgart (DE); Klaus Heyers, Reutlingen (DE)

(21) Appl. No.: 18/804,171

(22) Filed: Aug. 14, 2024

(30) Foreign Application Priority Data
Sep. 4, 2023 (DE) 10 2023 208 479.1

(51) Int. Cl. H03K 17/687

(52) U.S. Cl. CPC H03K 17/687

(57) ABSTRACT

A gate driver stage. The gate driver stage has a first power transistor including a first drain terminal and a first source terminal, with a second power transistor including a second drain terminal and a second source terminal. The first source terminal is electrically conductively connected to the second drain terminal and the first drain terminal is electrically conductively connected to a first voltage terminal. The second source terminal is electrically conductively connected to a second voltage terminal. The first voltage terminal has a first voltage value and the second voltage terminal has a second voltage value, the second voltage value being smaller than the first voltage value. A node is arranged between the first power transistor and the second power transistor, and is electrically conductively connected to a third gate terminal of a normally-off power transistor, and the third gate terminal can be controlled via the node.

### CROSS REFERENCE

The present application claims the benefit under 35 U.S.C. § 119 of German Patent Application No. DE 10 2023 208 479.1 filed on Sep. 4, 2023, which is expressly incorporated herein by reference in its entirety.

### FIELD

The present invention relates to a gate driver stage and to a method for operating a gate driver stage.

### BACKGROUND INFORMATION

Field effect transistors can exhibit instability when switching the gate. This occurs because the component switches back and forth between a voltage far above the threshold voltage and below the flatband voltage in operating mode. This negatively affects the conduction path of the component.

In a vehicle inverter, normally-off SiC MOSFETs are usually used as switches. They are switched off when negative voltage is applied. In the operation of the SiC MOSFETS, switching takes place back and forth between positive and negative gate voltages.

A disadvantage here is that a threshold voltage increase can occur over time.

This can be prevented by turning off the SiC MOSFET at 0 V.

A disadvantage, however, is that switching-on of the SiC MOSFET can occur again unintentionally, which is known as parasitic switching-on.

An object of the present invention is to overcome these disadvantages.

### SUMMARY

According to an example embodiment of the present invention, a gate driver stage comprises a first power transistor and a second power transistor. The first power transistor has a first drain terminal and a first source terminal. The second power transistor has a second drain terminal and a second source terminal. The first source terminal is electrically conductively connected to the second drain terminal. The first drain terminal is electrically conductively connected to a first voltage terminal, and the second source terminal is electrically conductively connected to a second voltage terminal. The first voltage terminal has a first voltage value and the second voltage terminal has a second voltage value, wherein the second voltage value is smaller than the first voltage value. A node is arranged between the first power transistor and the second power transistor, which node is electrically conductively connected to a third gate terminal of a normally-off power transistor, wherein the third gate terminal can be controlled via the node. According to an example embodiment of the present invention, the node is electrically conductively connected to a third voltage terminal, wherein the third voltage terminal has a third voltage value and the third voltage value is between the first voltage value and the second voltage value.

An advantage here is that the threshold voltage of the driven power transistor is long-term stable and parasitic switching-on of said power transistor is prevented.

In a development of the present invention, the third voltage value depends on a drain-source leakage current of the normally-off power transistor.

An advantage here is that the third voltage value only needs to be applied for a short time in order to avoid or significantly reduce the gate voltage instability, since the optimal voltage can be used.

In a further embodiment of the present invention, the third voltage value depends on a temperature of the normally-off power transistor.

In a development of the present invention, the voltage value is a fixed value in the range between 0 V and the threshold voltage of the normally-off power transistor.

An advantage here is that the switching process of the controlled power transistor is low-loss.

In a development of the present invention, a parallel circuit with a first resistor, a second resistor, a first diode and a second diode is arranged between the node and the third gate terminal, wherein the first resistor and the first diode are connected in parallel to the second resistor and to the second diode and the second diode has a forward direction opposite to the first diode.

An advantage here is that the switching process can be controlled within the controlled power transistor. In other words, oscillations of the controlled power transistor are prevented.

In a further example embodiment of the present invention, the normally-off power transistor is a SiC MOSFET.

A method according to an example embodiment of the present invention for operating a gate driver stage with a first power transistor comprising a first drain terminal and a first source terminal, with a second power transistor comprising a second drain terminal and a second source terminal, wherein the first source terminal is electrically conductively connected to the second drain terminal and the first drain terminal is electrically conductively connected to a first voltage terminal, wherein the second source terminal is electrically conductively connected to a second voltage terminal, wherein the first voltage terminal has a first voltage value and the second voltage terminal has a second voltage value, wherein the second voltage value is smaller than the first voltage value, wherein a node is arranged between the first power transistor and the second power transistor, which node is electrically conductively connected to a third gate terminal of a normally-off power transistor, wherein the third gate terminal can be controlled via the node, wherein the node is electrically conductively connected to a third voltage terminal, wherein the third voltage terminal has a third voltage value and the third voltage value is between the first voltage value and the second voltage value, wherein the first power transistor, the second power transistor, and the normally-off power transistor are switched off, comprises switching on the second power transistor at a first time. The method furthermore comprises switching off the second power transistor at a second time and switching on the first power transistor at a third time.

An advantage here is that the voltage at the third gate terminal can be set.

In a development of the present invention, a drain-source leakage current of the normally-off power transistor is detected by means of a current sense terminal and the third voltage value is set depending on the drain-source leakage current of the normally-off power transistor.

An advantage here is that the third voltage value can be set optimally.

In a further example embodiment of the present invention, a temperature of the normally-off power transistor is detected by means of a temperature sensor and the third voltage value is set depending on the temperature of the normally-off power transistor.

Further advantages can be found in the following description of exemplary embodiments and the disclosure herein.

### BRIEF DESCRIPTION OF THE DRAWINGS

The present invention is explained below with reference to preferred embodiments and the figures.

FIG. 1 shows a gate driver stage according to an example embodiment of the present invention.

FIG. 2 shows a method for operating the gate driver according to an example embodiment of the present invention.

FIG. 3 shows a voltage curve according to an example embodiment of the present invention at the gate of the normally-off power transistor.

### DETAILED DESCRIPTION OF EXAMPLE EMBODIMENTS

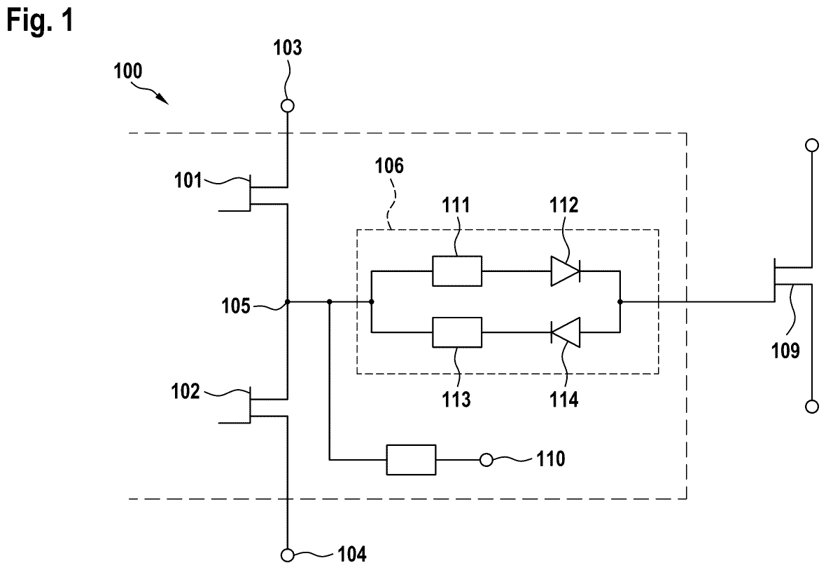

FIG. 1 describes a gate driver stage 100 with a first power transistor 101 and a second power transistor 102. The first power transistor 101 has a first drain terminal and a first source terminal. The second power transistor 102 has a second drain terminal and a second source terminal. The first source terminal and the second drain terminal are electrically conductively connected, i.e., the first power transistor 101 and the second power transistor 102 are connected in series. The first drain terminal is connected to a first voltage terminal 103 having a first voltage value. The second source terminal is connected to a second voltage terminal 104 having a second voltage value. The second voltage value is smaller than the first voltage value. A node 105 is arranged between the first power transistor 101 and the second power transistor 102. The node 105 is electrically conductively connected to a third gate terminal of a normally-off power transistor 109, for example a SiC MOSFET. This means that the third gate terminal can be controlled via the node 105. The node 105 is likewise electrically conductively connected to a third voltage terminal 110, wherein the third voltage terminal 110 has a third voltage value and the third voltage value is between the first voltage value and the second voltage value. In other words, the third gate terminal is driven by means of three voltage levels. The middle voltage or the third voltage value is used immediately before turning on or switching on the normally-off power transistor 109 to charge interface states with electrons, so that the positive interface charge is reduced. This reduces the electrical field at the interface after the turning-on, whereby the threshold voltage drift, the so-called gate switching instability, or GSI for short, is reduced.

In an exemplary embodiment not shown, the node 105 and the third gate terminal are directly connected by means of a line. In another exemplary embodiment not shown, a resistor is arranged between the node 105 and the third gate terminal. This arrangement ensures that the power transistor 109 is switched on slowly, so that no oscillations occur during the switching process. In a further exemplary embodiment, as shown in FIG. 1, a parallel circuit 106 with a first resistor 111, a second resistor 113, a first diode 112, and a second diode 114 is arranged between the node 105 and the third gate terminal, wherein the first resistor 111 and the first diode 112 are connected in parallel to the second resistor 113 and to the second diode 114 and the second diode 114 has a forward direction opposite to the first diode 112. This means that the first diode 112 is connected in anti-parallel to the second diode 114.

Both the resistor and the parallel circuit 106 can be implemented within a driver ASIC, or as discrete components between the driver ASIC and the power transistor to be controlled, or integrated in the power MOSFET.

The gate driver stage according to the present invention is used in the electric drive train of electrically driven or hybrid-driven vehicles, i.e., in DC/DC converters and inverters. Additionally, the gate driver stage is used in a vehicle charger.

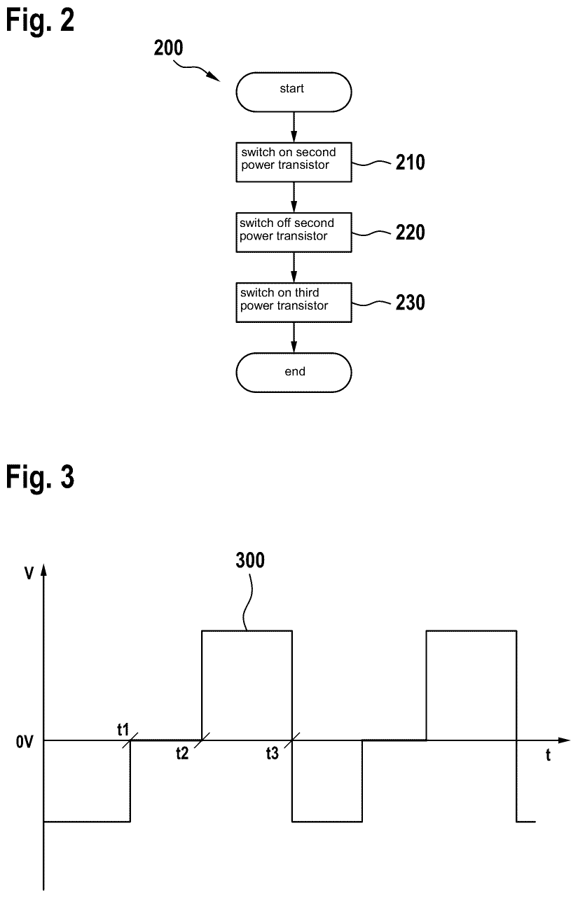

FIG. 2 shows the method 200 for operating a gate driver stage. In the initial state of the gate driver stage, the first power transistor, the second power transistor, and the normally-off power transistor are switched off. The method 200 starts with a step 210, in which the second power transistor is switched on at a first time. The second voltage terminal is thus electrically conductively connected to the third gate terminal, so that the second voltage value is applied to the third gate terminal for a first time period. This second voltage value is preferably negative. In a following step 220, the second power transistor is switched off at a second time. The third voltage terminal is thus electrically conductively connected to the third gate terminal, so that the third voltage value is applied to the third gate terminal for a second time period. This third voltage value, for example, has a fixed value in the range between 0 V and the threshold voltage. This value is determined by a measurement at the normally-off power transistor or a measurement at the module during the production process and is fixedly set in the module or the gate driver stage, which is part of the module. Alternatively, the third voltage value has a small positive value that depends on the drain-source leakage current of the normally-off power transistor or on the temperature of the normally-off power transistor. In a following step 230, the first power transistor is switched on at a third time. The first voltage terminal is thus electrically conductively connected to the third gate terminal. This first voltage value is positive and is above the threshold voltage, so that the first voltage value is applied to the third gate terminal for a third time period, so that the normally-off power transistor is switched or switches on. The method is subsequently terminated or starts again with step 210. In other words, the gate voltage of the normally-off power transistor can be set in steps.

FIG. 3 shows the voltage curve 300, which is generated at the third gate terminal by means of the method 200 of FIG. 2. The x-axis shows the time, and the y-axis shows the voltage value applied to the third gate terminal. In the initial state of the method for operating the gate driver stage, the first power transistor, the second power transistor, and the normally-off power transistor are switched off. This means that no drain-source current flows in the normally-off power transistor. Alternatively, a small drain-source leakage current flows, which is below a particular limit value. The particular limit value is determined by power losses or premature turning-on of the normally-off power transistor. The first voltage value is, for example, 18 V, the second voltage value is, for example, −5 V, and the third voltage value is, for example, 0 V. After the second power transistor is switched on, the second voltage value is applied to the third gate terminal. This means that the normally-off power transistor is switched off. After a first time period, the second circuit breaker is switched off at the second time, for example via a control signal of a control device. The third voltage value is thus applied to the third gate terminal and serves to prepare the turning-on of the normally-off power transistor. There is still no significant drain-source current flowing in the normally-off power transistor, but the interface states are charged with electrons. This has a direct influence on the electrical field at the interface immediately after the turning-on. After a second time period, the first power transistor is switched on at the third time, for example via a further control signal of the control device. As a result, the normally-off power transistor switches on and a drain-source current flows through it. In other words, by means of the middle voltage value used immediately before turning on the normally-off power transistor, the interface states are charged with electrons, whereby the electrical field at the interface is reduced immediately after the turning-on and less threshold voltage drift is generated.

What is claimed is:

1. A gate driver stage, comprising:
a first power transistor including a first drain terminal and a first source terminal;
a second power transistor including a second drain terminal and a second source terminal, wherein the first source terminal is electrically conductively connected to the second drain terminal and the first drain terminal is electrically conductively connected to a first voltage terminal, wherein the second source terminal is electrically conductively connected to a second voltage terminal, wherein the first voltage terminal has a first voltage value and the second voltage terminal has a second voltage value, wherein the second voltage value is smaller than the first voltage value;
a node arranged between the first power transistor and the second power transistor, and being electrically conductively connected to a third gate terminal of a normally-off power transistor, wherein the third gate terminal can be controlled via the node;
wherein the node is electrically conductively connected to a third voltage terminal, wherein the third voltage terminal has a third voltage value and the third voltage value is between the first voltage value and the second voltage value.

2. The gate driver stage according to claim 1, wherein the third voltage value depends on a drain-source leakage current of the normally-off power transistor.

3. The gate driver stage according to claim 1, wherein the third voltage value depends on a temperature of the normally-off power transistor.

4. The gate driver stage according to claim 1, wherein the third voltage value is a fixed value in the range between 0 V and a threshold voltage of the normally-off power transistor.

5. The gate driver stage according to claim 1, wherein a parallel circuit with a first resistor, a second resistor, a first diode, and a second diode is arranged between the node and the third gate terminal, wherein the first resistor and the first diode are connected in parallel to the second resistor and to the second diode, and the second diode has a forward direction opposite to the first diode.

6. The gate driver stage according to claim 1, wherein the normally-off power transistor is a SiC MOSFET.

7. A method for operating a gate driver stage with a first power transistor including a first drain terminal and a first source terminal, with a second power transistor including a second drain terminal and a second source terminal, wherein the first source terminal is electrically conductively connected to the second drain terminal and the first drain terminal is electrically conductively connected to a first voltage terminal, wherein the second source terminal is electrically conductively connected to a second voltage terminal, wherein the first voltage terminal has a first voltage value, and the second voltage terminal has a second voltage value, wherein the second voltage value is smaller than the first voltage value, wherein a node is arranged between the first power transistor and the second power transistor, the node being electrically conductively connected to a third gate terminal of a normally-off power transistor, wherein the third gate terminal can be controlled via the node, wherein the node is electrically conductively connected to a third voltage terminal, wherein the third voltage terminal has a third voltage value and the third voltage value is between the first voltage value and the second voltage value, wherein the first power transistor, the second power transistor, and the normally-off power transistor are switched off, the method comprising the following steps:
switching on the second power transistor at a first time;
switching off the second power transistor at a second time; and
switching on the first power transistor at a third time.

8. The method for operating a gate driver stage according to claim 7, wherein a drain-source leakage current of the normally-off power transistor is detected using a current sense terminal and the third voltage value is set depending on the drain-source leakage current of the normally-off power transistor.

9. The method for operating a gate driver stage according to claim 7, wherein a temperature of the normally-off power transistor is detected using a temperature sensor and the third voltage value is set depending on the temperature of the normally-off power transistor.
